(19) United States
(12) Patent Application Publication
(10) Pub. No.: US 2026/0198060 A1
(43) Pub. Date: Jul. 9, 2026

(54) L-SHAPED BACKSIDE CONTACT

(71) Applicant: INTERNATIONAL BUSINESS MACHINES CORPORATION, Armonk, NY (US)

(72) Inventors: Tsung-Sheng Kang, Ballston Lake, NY (US); Saidjafarzoda ILHOM, Selkirk, NY (US); Tao Li, Slingerlands, NY (US); Ruilong Xie, Niskayuna, NY (US)

(21) Appl. No.: 19/009,030

(22) Filed: Jan. 3, 2025

(51) Int. Cl. H10D 64/23; H10D 30/00; H10D 30/01; H10D 62/10; H10D 84/01; H10D 84/83

(52) U.S. Cl. CPC H10D 64/254; H10D 30/0198; H10D 84/0149; H10D 84/8312; H10D 84/832; H10D 30/502; H10D 62/121

(57) ABSTRACT

A semiconductor device includes a frontside, a backside, a bottom source/drain region and a top source/drain region. A stepped backside contact is connected to the bottom source/drain region. The stepped backside contact has a relief, wherein the relief provides increased distance between the stepped backside contact and a first metal line on the backside.

### BACKGROUND

The present invention generally relates to semiconductor devices and processing methods, and more particularly to wiring connections between a frontside and a backside of a semiconductor device.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

Stacked field effect transistors (FETs) include stacked source/drain regions. Making connections to these stacked FETs is difficult due to high device densities. To separate contacts between top and bottom source/drain regions for stacked FETs, the top source/drain regions can employ frontside contacts, while the bottom source/drain regions can employ backside contacts. However, the frontside of a wafer is known to be very tight in space due to high device densities and many wiring paths.

Alternatively, deep vias can be employed to connect the top source/drain regions to a backside power distribution network (BSPDN) on a backside of the wafer. The deep vias consume a substantial amount of areal and volumetric space. Spacings between supply voltage lines (e.g., VSS and VDD) is also problematic as the supply voltage lines are placed in close proximity to reduce a lateral distance from the deep via to the top source/drain regions. If the spacing between the supply voltage lines is too close, shorts can occur, and if the spacing is too distant space is wasted.

### SUMMARY

In accordance with an embodiment of the present invention, a semiconductor device includes a frontside, a backside, a bottom source/drain region and a top source/drain region. A stepped backside contact is connected to the bottom source/drain region. The stepped backside contact has a relief, wherein the relief provides increased distance between the stepped backside contact and a first metal line on the backside.

In accordance with another embodiment of the present invention, a semiconductor device includes a frontside, a backside, a bottom source/drain region and a top source/drain region. A stepped backside contact is connected to the bottom source/drain region. The stepped backside contact has a relief, wherein the relief provides a recess to increase a distance between the stepped backside contact and a first metal line on the backside. A deep via is connected to the top source/drain region. A backside power distribution network includes the first metal line connected to the deep via and a second metal line connected to the stepped backside contact.

In accordance with another embodiment of the present invention, a method of fabricating a semiconductor device includes forming a bottom nanosheet stack and a top nanosheet stack on a substrate, recessing the top nanosheet stack and a first portion the bottom nanosheet stack concurrently to expose of a first region of the substrate and recessing a second portion of the bottom nanosheet stack to expose a second portion of the substrate while concurrently etching a first recess in the substrate in the first region. The first recess is further recessed in the substrate in the first region and a second recess is formed in the substrate in the second region to form a stepped recess. A sacrificial placeholder is formed in the stepped recess and a bottom source/drain region is formed on the sacrificial placeholder. A top source/drain region is formed over the bottom source/drain region. A deep via is formed and is connected to the top source/drain region. The sacrificial placeholder is removed, and a stepped backside contact is formed in place of the sacrificial placeholder. The stepped backside contact is connected to the bottom source/drain region.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a cross-sectional view, taken at section line Y as shown in an inset (and referred to as section Y), of a semiconductor device with nanosheet stacks in a stairway configuration, in accordance with an embodiment of the present invention;

FIG. 2 shows a cross-sectional view, taken at section line Y, of the semiconductor device with sidewall spacers recessed, in accordance with an embodiment of the present invention;

FIG. 3 shows a cross-sectional view, taken at section line Y, of the semiconductor device with top and bottom nanosheet stacks concurrently etched, in accordance with an embodiment of the present invention;

FIG. 4 shows a cross-sectional view, taken at section line Y, of the semiconductor device with the bottom nanosheet stack etched while concurrently etching a substrate, in accordance with an embodiment of the present invention;

FIG. 5 shows a cross-sectional view, taken at section line Y, of the semiconductor device with the substrate further etched to form a stepped recess, in accordance with an embodiment of the present invention;

FIG. 6 shows a cross-sectional view, taken at section line Y, of the semiconductor device with the stepped recess filled to form a sacrificial placeholder, in accordance with an embodiment of the present invention;

FIG. 7 shows a cross-sectional view, taken at section line Y, of the semiconductor device with stacked epitaxial regions formed for source/drain regions, in accordance with an embodiment of the present invention;

FIG. 8 shows a cross-sectional view, taken at section line Y, of the semiconductor device with a deep via, top contacts and a back end of line layer formed, in accordance with an embodiment of the present invention;

FIG. 9 shows a cross-sectional view, taken at section line Y, of the semiconductor device with a carrier wafer installed and a backside of the semiconductor device processed to remove the sacrificial placeholder and install a backside contact with a stepped profile having a relief, in accordance with an embodiment of the present invention;

FIG. 10 shows a cross-sectional view, taken at section line Y, of the semiconductor device with a dielectric layer formed on the backside of the semiconductor device filling in the relief, in accordance with an embodiment of the present invention;

FIG. 11 shows a cross-sectional view, taken at section line Y, of the semiconductor device with metal lines or power supply lines formed on the backside of the semiconductor device with the dielectric layer forming a T-shape therebetween within the relief, in accordance with an embodiment of the present invention; and

FIG. 12 shows a cross-sectional view, taken at section line Y, of the semiconductor device with metal lines or power supply lines formed on the backside of the semiconductor device with the dielectric layer forming an S-shape therebetween within the relief, in accordance with an embodiment of the present invention.

### DETAILED DESCRIPTION

In accordance with embodiments of the present invention, devices and methods are described which include connections between a frontside and a backside of a semiconductor device. Conductive structures are provided to span lateral distances to make connections between components while maintaining sufficient distance and dielectric isolation between conductive components. In an embodiment, a backside contact that connects to a bottom source/drain region includes a relief to permit extra dielectric material between supply voltage lines in a backside power distribution network. The relief of the backside contact provides additional distance from a voltage power supply line while maintaining a distance from a deep via employed to connect to a top source/drain region. In an embodiment, the backside contact includes an L-shaped cross-section with the relief being opposite the bottom source/drain region and adjacent to the deep via.

In an embodiment, a method for fabricating a semiconductor device with stacked field effect transistors (FETs) is provided. Using a staircase nanosheet (NS) stack having two levels corresponding to top and a bottom source/drain regions, dummy gate material is applied and etched to form dummy gates. A spacer layer is deposited and etched to form sidewall spacers of the dummy gates. The sidewall spacers are further etched to recess the sidewall spacers. A source/drain (S/D) recess is performed which concurrently etches a space in a substrate on which the nanosheet stack is applied. The etch of the substrate forms a first recess in the substrate which supplies room for a sacrificial placeholder. A subsequent recess etch increases the first recess to form an L-shaped recess in the substrate. A dielectric material is formed in the L-shaped recess. A deep via is formed which connects to a top S/D region. The sacrificial placeholder is replaced by a backside contact with the L-shaped recess. The backside contact includes a relief. A backside power distribution network (BSPDN) is formed and connects to the deep via. The BSPDN includes supply voltage lines. One power line is formed adjacent to the relief. The relief permits extra space and dielectric isolation for the one power line. A backside interlevel dielectric (BILD) layer fills the relief and can form a T-shape or an S-shape cross-section in a region adjacent to the power lines of the BSPDN.

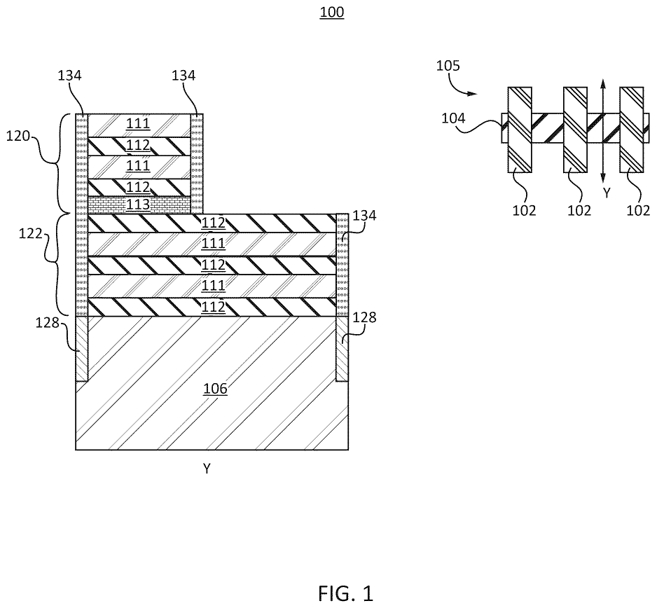

Referring now to the drawings in which like numerals represent the same or similar elements and initially to FIG. 1, devices and methods for manufacturing a nanosheet field effect transistor (FET) device are shown in accordance with embodiments of the present invention. A wafer 100 includes a substrate 106 having one or more layers on which FET devices will be fabricated. FIG. 1 depicts a section Y taken at corresponding section line Y in an inset 105. Inset 105 shows gate lines 102 and active region lines 104 for reference. Corresponding Y views are depicted throughout the FIGS. Active region lines 104 represent S/D regions for transistor devices to be formed, and gate lines 102 are represented for such transistor devices. Transistor channels are formed on the active region lines 104 below the gate lines 102.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A stairway nanosheet configuration includes an upper nanosheet stack 120 applied to a lower nanosheet stack 122, which is applied to or formed on the substrate 106. In an embodiment, nanosheets 111, 112 are included in the upper nanosheet stack 120 and the lower nanosheet stack 122. The nanosheets 111, 112 include alternating semiconductor layers of different semiconductor materials. The alternating layers can be epitaxially grown using different chemistries to form layers having different properties. In an embodiment, the semiconductor layers of the nanosheets 112 form transistor channels and can include, e.g., Si, although other semiconductor materials can be employed. The semiconductor layers of the nanosheets 111 can include sacrificial layers and can include, e.g., SiGe. A nanosheet 113 disposed between the upper nanosheet stack 120 and the lower nanosheet stack 122 can include SiGe with a greater Ge concentration to permit selective removal of the nanosheet 113 relative to the nanosheets 111. The nanosheet 113 and nanosheets 111 are sacrificial.

A single or multiple nanosheet stack can be patterned. In an embodiment, a hard mask (not shown) may be formed by blanket depositing a layer of hard mask material, providing a patterned photoresist on top of the layer of hard mask material, and then etching the layer of hard mask material to provide the hard mask pattern for etching the nanosheet stacks. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

The substrate 106 can be etched to form shallow trenches therein. Shallow trench isolation (STI) regions or STI 128 are formed in the etched trenches. STI 128 can be formed by depositing dielectric material, such as, e.g., SiO₂, SiOₓN_{y}, SiCO or other suitable compounds. STI 128 can be deposited using chemical vapor deposition (CVD), although other deposition methods can be employed. The STI 128 can then be etched, e.g., by RIE, to a level of the substrate 106.

A dummy gate material (not shown) for dummy gates is blanketed over the wafer 100 followed by a blanket deposition of a hard mask material to later form a patterned hard mask (not shown), e.g., by using photolithographic patterning. The dummy gate material can include a polysilicon, amorphous Si or other selectively removeable material. The hard mask material is patterned to form a hard mask. The hard mask is employed to etch the dummy gate material. Then, a deposition process is employed to form spacers 134. Spacers 134 can include a nitride, an oxide, such as silicon dioxide, although other dielectric materials can be employed. A spacer etch removes spacer material from horizontal surfaces.

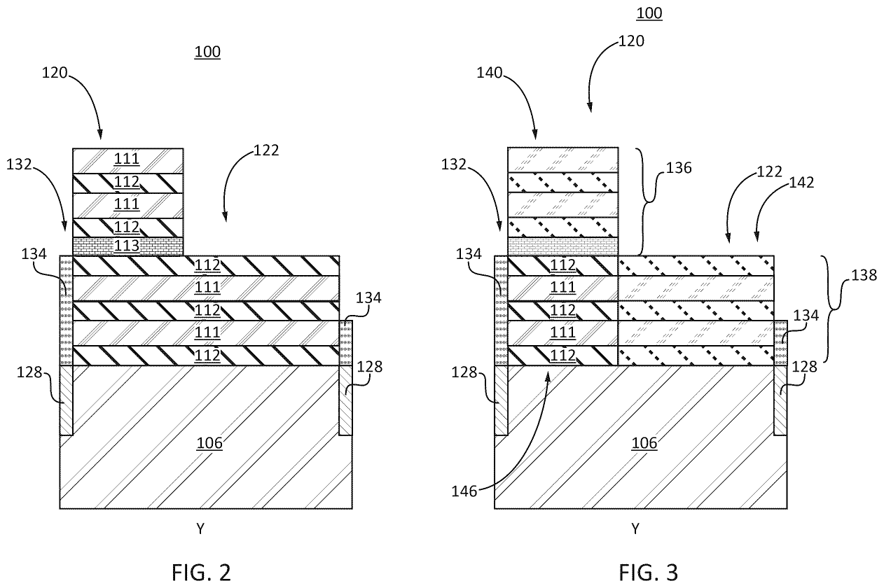

Referring to FIGS. 2 and 3, the hard mask and spacers 134 can be employed as an etch mask to recess the upper nanosheet stack 120 and the lower nanosheet stack 122, concurrently to expose the substrate 106 in a first region. FIG. 2 shows the wafer 100 just prior to S/D recessing, and FIG. 3 shows the wafer 100 just after a first S/D recess etch. The first S/D recess etch includes an anisotropic etch, such as, e.g., a reactive ion etch (RIE) or ion beam etching (IBE). The spacers 134 are eroded in a spacer etch the spacers 134 adjacent to the upper nanosheet stack 120 being etched faster than the spacers 134 adjacent to the lower nanosheet stack 122. This forms recessed spacer material 132.

Processing can continue with the formation of inner spacers (not shown), which are formed and include a dielectric material. In an embodiment, the inner spacers are formed using exposed portions of the nanosheets 111 in S/D canyons (not shown), which undergo a recess etch followed by a sidewall deposition using a dielectric (e.g., SiO₂) in recessed portions.

A first S/D recess etches the upper nanosheet stack 120 and the lower nanosheet stack 122 concurrently to remove a portion 136 of the upper nanosheet stack 120 and a portion 138 of the lower nanosheet stack 122. It should be noted that the upper nanosheet stack 120 is depicted in a lighter form 140 (e.g., broken lines) to show that the upper nanosheet stack 120 is etched in the portion 136 to remove a portion of the upper nanosheet stack 120 in front of the lighter form 140. Likewise, the lower nanosheet stack 122 is depicted in a lighter form 142 to show that the lower nanosheet stack 122 is etched in the portion 138 to remove a portion of the lower nanosheet stack 122 in front of the lighter form 142. A portion 146 of the lower nanosheet stack 122 remains after the first S/D recess etch.

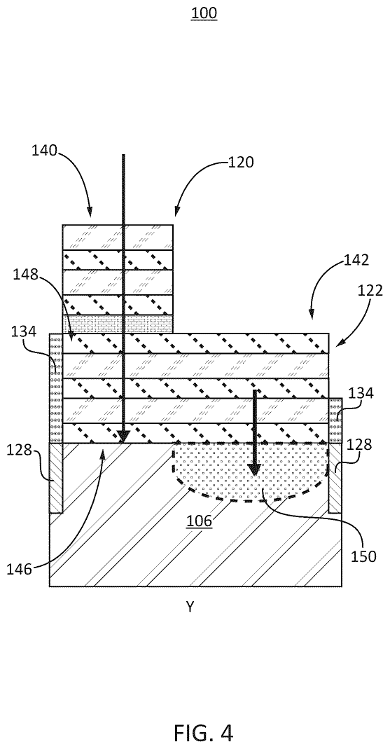

Referring to FIG. 4, the portion 146 of the lower nanosheet stack 122 is removed by a second S/D recess etch or by continuing the first S/D recess etch to expose a second region of the substrate 106. During the second or continued S/D recess etch, the substrate 106 is likewise etched to form a recess 150 therein. The recess 150 provides a portion of a cavity or opening that will be employed for the formation of a placeholder and eventually a backside contact in accordance with embodiments of the present invention.

It should be noted that the lower nanosheet stack 122 is depicted in a lighter form 148 to show that the lower nanosheet stack 122 is etched in the portion 146 to remove a portion of the lower nanosheet stack 122 in front of the lighter form 148.

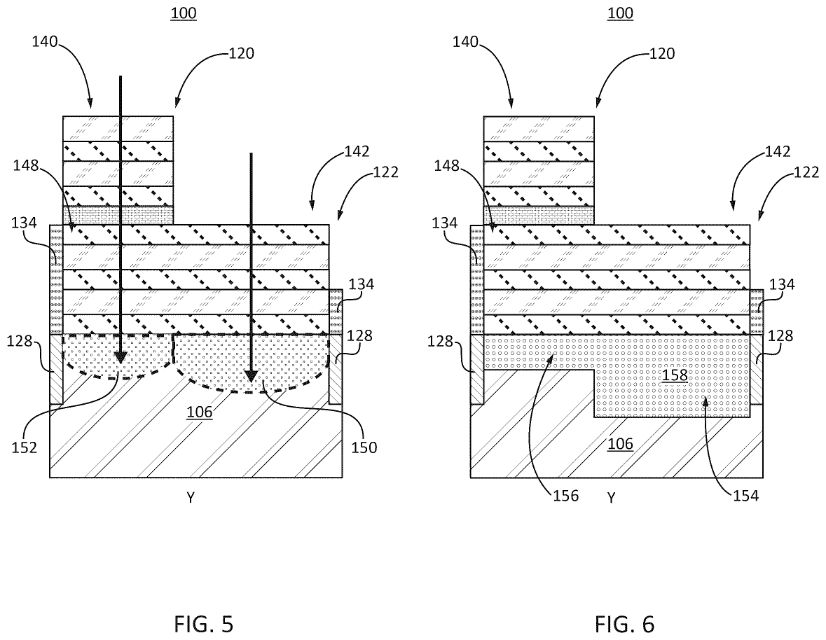

Referring to FIG. 5, the second or continued S/D recess etch can be extended to further etch the substrate 106. A recess 152 is formed and the recess 150 is extended deeper into the substrate 106. The recess 150 and the recess 152 form a trench having two levels or heights therein to form an L-shaped cross-section.

Referring to FIG. 6, the recess 150 and the recess 152 formed in the substrate 106 can be filled by forming a sacrificial placeholder 154 therein. The sacrificial placeholder 154 can include epitaxially grown materials, such as e.g., SiGe, using the crystal structure of the substrate 106 (e.g., a monocrystalline Si material) to initiate crystal growth. The sacrificial placeholder 154 can include SiGe or other epitaxial grown material that can be selectively removed relative to the substrate 106. The sacrificial placeholder 154 includes a thicker portion 158 and a thinner portion 156, which are connected and integrally formed.

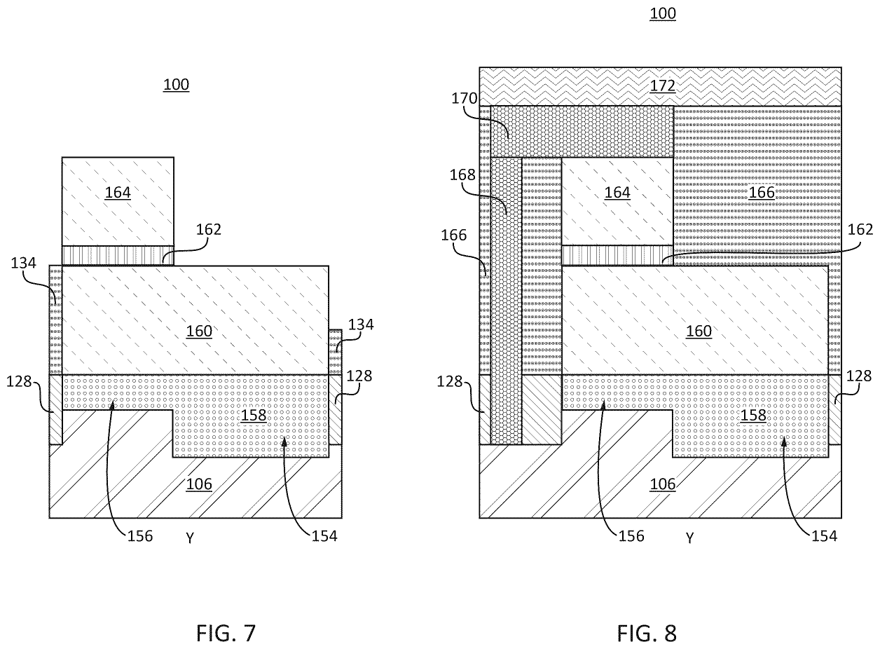

Referring to FIG. 7, an epitaxial growth process is performed to form bottom S/D regions 160. Bottom S/D regions 160 are employed to form bottom transistors of the stacked FET device under construction. Bottom S/D regions 160 can include Si or SiGe. In an embodiment, the bottom S/D regions 160 can be designated as P-type or N-type devices. If the bottom S/D regions 160 include N-type devices then the bottom S/D regions 160 can include Si. If the bottom S/D regions 160 include P-type devices then the bottom S/D regions 160 can include SiGe. The bottom S/D regions 160 can be appropriately doped during the formation of the bottom S/D regions 160 by epitaxial growth. For example, the bottom S/D regions 160 can be doped by introducing p dopants (e.g., B, Ga, etc.) during epitaxial formation. Similarly, the bottom S/D regions 160 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

A dielectric layer 162 is deposited over the bottom S/D regions 160 to provide electrical isolation between the bottom S/D regions 160 and top S/D regions 164 to be formed.

The dielectric layer 162 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 162 can be deposited using CVD, although other deposition methods can be employed.

An epitaxial growth process is employed to grow top S/D regions 164. Top S/D regions 164 will form S/D regions for top FETs for the stacked FET device under fabrication. The top S/D regions 164 can utilize the nanosheets 112 to initiate crystal growth. The top S/D regions 164 are separated from the bottom S/D regions 160 by the dielectric layer 162.

Processing continues with the formation of a dielectric layer 166 (e.g., an interlevel dielectric layer (ILD) (FIG. 8)). The dielectric layer 166 is deposited over the wafer 100. The same process and materials used for the formation of dielectric layer 162 can be employed for dielectric layer 166, although dielectric layer 166 may include a different composition to enable etch selectivity. The dielectric layer 166 is planarized, e.g., by chemical mechanical polishing (CMP), which also removes the hard mask and portions of the spacers 134.

Dummy gate material and nanosheets 111 (sacrificial) are removed by etching. A high dielectric constant (high-K) gate dielectric is formed followed by a gate metal fill. This process is known as a replacement metal gate process to form gate structures (e.g., High-K Metal Gates (HKMG)) for selectively activating top FETs and bottom FETs. The gate structures are separated by middle dielectric isolation (MDI) (not shown).

Referring to FIG. 8, a deep via 168 is formed through the dielectric layer 16 and through the STI 128 to contact the substrate 106. A lithographic process is employed to pattern and etch an opening for the deep via 168. Middle of the line (MOL) contacts can also be formed to make connections with the top S/D regions 164 and/or the bottom S/D regions 160 from a top side of the device. Trenches or holes are formed in the dielectric layer 166, which forms a top ILD. The trenches or holes expose the underlying active materials for the top S/D regions 160 (and/or the bottom S/D regions 160).

In some embodiments, a silicide liner, such as Ti, Ni, NiPt is deposited first on the top S/D regions 164 and/or the bottom S/D regions 160, then a diffusion barrier can be formed in the trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to complete the deep via 168 and contacts 170.

Processing continues with the formation of back end of the line (BEOL) layer 172, which can include metal structures and dielectric layers to complete the top side of the stacked FET device and provide electrical access to the devices formed.

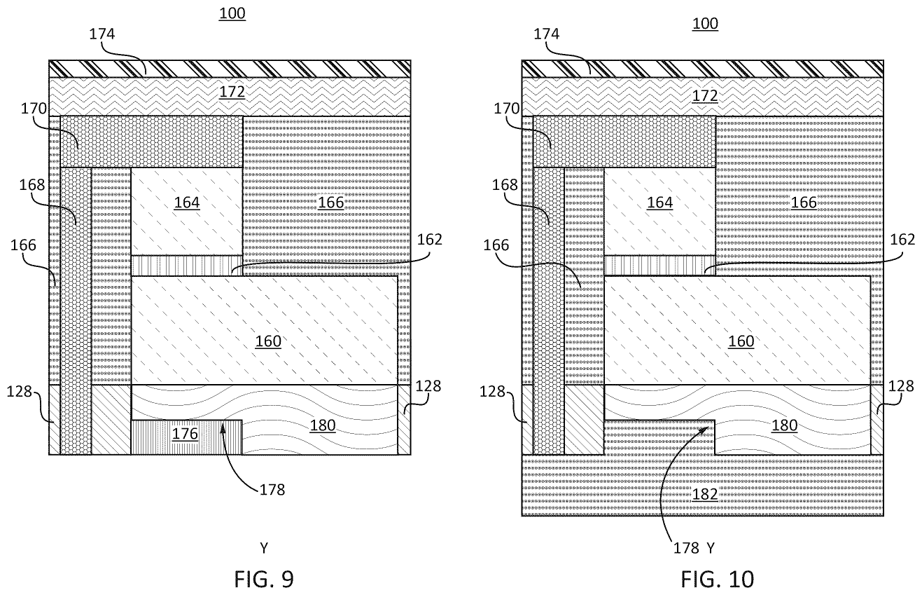

Referring to FIG. 9, a carrier wafer 174 can be bonded to the BEOL layer 172. The carrier wafer 174 provides support and transportability to the wafer 100 for further processing which includes flipping the wafer 100 and removing portions of a bottom side of the stacked FET device.

To continue processing, the wafer 100 can be flipped to process features on the bottom side of the stacked FET device. However, for clarity and consistency, the stacked FET device will be shown in the FIGS. in a same orientation as previously described with continued and consistent reference to bottom/top or backside/frontside. The substrate 106 is polished down from the bottom side of the wafer 100, e.g., by CMP. A portion 176 of the substrate 106 remains and will be removed in later steps.

The sacrificial placeholders 154 are exposed and removed by a selective etch that is selective to the STI 128 and the bottom S/D regions 160. In some embodiments, a silicide liner, such as Ti, Ni, NiPt is deposited first on the bottom S/D regions 160, then a diffusion barrier can be formed in the trenches prior to a conductive fill. The diffusion barrier can include, e.g., TiN, TaN, or similar materials.

A conductive fill is performed to fill the trench formed by removing the sacrificial placeholder 154 on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form a stepped backside contact for the backside contact 180. The portion 176 of the substrate 106 that remains provides a relief 178 that will be employed in later steps to provide a greater distance between the backside contact 180 and a power line.

Referring to FIG. 10, the remainder of the substrate 106 is removed including the portion 176 by a selective etch. A dielectric layer 182 is formed over the backside of the wafer 100 including the STI 128, the backside contact 180 and the deep via 168. The dielectric layer 182 includes a material that is selectively removeable relative to the STI 128, the backside contact 180 and the deep via 168. The dielectric layer 182 can include a backside interlevel dielectric (ILD) layer.

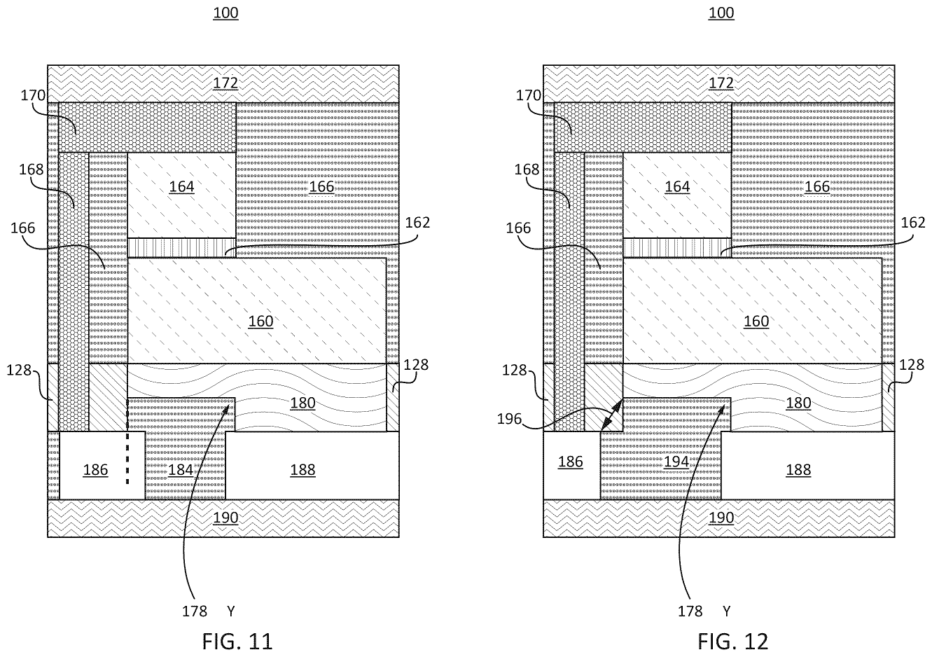

Referring to FIG. 11, the dielectric layer 182 is patterned using a lithographic process to form an etch mask. The etch mask is employed to etch openings for metal lines 186 and 188 in the dielectric layer 182. An etch process exposed an end portion of the deep via 168 and the backside contact 180.

A conductive fill is performed to fill the openings. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form metal lines 186 and 188. In an embodiment, the metal lines 186 and 188 include power signals although the metal lines 186 and 188 can include signal lines. The metal lines 186 and 188 can include supply voltage lines, e.g., a negative supply voltage (VSS) and/or a positive supply voltage (VDD). In an embodiment, the metal line 186 can include a VSS line while the metal line 188 includes a VDD line. This can be switched or both lines can be of a same supply voltage type.

The metal line 186 connects to the deep via 168, and the metal line 188 connects directly to a thicker portion of the backside contact 180. The relief 178 in the backside contact 180 provides a larger gap or distance between the backside contact 180 and the metal line 186. This larger gap results in better dielectric isolation between the backside contact 180 and the deep via 168 as well as reduced capacitance therebetween.

The relief 178 provides more dielectric material to increase a distance between the backside contact 180 and the metal line 186 (e.g., power line). The backside contact 180 can include an L-shaped cross-section or stepped profile (e.g., a stepped backside contact). In the embodiment shown, the metal line 186 connects to the top S/D region 164 through the deep via 168 while metal line 188 connects to the bottom S/D region 160. Dielectric material 184 surrounded by the metal lines 186, 188 and the backside contact 180 forms a T-shape in cross-section. A top of the T-shape is formed in the relief 178 while the vertical portion of the T-shape separates the adjacent metal lines 186 and 188. The relief 178 also increases process window since at least the metal line 186 has greater placement leeway under the backside contact 180 within a region of the relief 178. A dashed line 192 highlights an overlap between the metal line 186 and an end portion of the backside contact 180. The metal line 186 can be shifted either way (e.g., left or right) and still have a sufficient distance from the backside contact 180.

Processing continues with the continued formation of a backside interconnect layer 190, which can include one or more metal structure layers and dielectric layers to complete a backside of the wafer 100. The backside interconnect layer 190 and the metal lines 186 and 188 can be part of a backside power distribution network (BSPDN).

Referring to FIG. 12, in another embodiment, the dielectric layer 182 patterned using a lithographic process to form an etch mask. The etch mask is employed to etch openings for metal lines 186 and 188 in the dielectric layer 182. An etch process exposes an end portion of the deep via 168 and the backside contact 180. The relief 178 provides more dielectric material to provide the greater distance between the backside contact 180 and the metal line 186 (e.g., power line). The backside contact 180 can include an L-shaped cross-section or stepped profile. In the embodiment shown, the metal line 186 connects to the top S/D region 164 through the deep via 168 while the metal line 188 connects to the bottom S/D region 160. Dielectric material 184 surrounded by the metal lines 186, 188 and the backside contact 180 forms an S-shape in cross-section. A top of the S-shape is formed in the relief 178 while a bottom portion of the S-shape separates the adjacent metal lines 186 and 188. The relief 178 also increases process window since at least the metal line 186 has greater placement leeway under the backside contact 180 within a region of the relief 178. An arrow 196 shows an increased tip-to-tip distance between the metal line 186 and an end portion of the backside contact 180. The metal line 186 can be shifted either way (e.g., left or right) and still have a sufficient distance from the backside contact 180. In the embodiment shown, the metal line 186 is shifted so as to not overlap with the backside contact 180.

Processing continues with the formation of the backside interconnect layer 190, which can include one or more metal structure layers and dielectric layers to complete a backside of the wafer 100. The backside interconnect layer 190 and the metal lines 186 and 188 can be part of the BSPDN.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a frontside and a backside;
a bottom source/drain region;
a top source/drain region; and
a stepped backside contact connected to the bottom source/drain region, the stepped backside contact having a relief, wherein the relief provides increased distance between the stepped backside contact and a first metal line on the backside.

2. The semiconductor device of claim 1, further comprising:
a deep via connected to the top source/drain region and the first metal line.

3. The semiconductor device of claim 2, wherein the relief is adjacent to the deep via.

4. The semiconductor device of claim 1, further comprising a dielectric layer between the first metal line and a second metal line on the backside.

5. The semiconductor device of claim 4, wherein the dielectric layer forms a T-shape in the relief and in a region between the first metal line and the second metal line.

6. The semiconductor device of claim 4, wherein the dielectric layer forms an S-shape in the relief and in a region between the first metal line and the second metal line.

7. The semiconductor device of claim 1, wherein the first metal line includes a supply voltage line in a backside power distribution network.

8. A semiconductor device, comprising:
a frontside and a backside;
a bottom source/drain region;
a top source/drain region;
a stepped backside contact connected to the bottom source/drain region, the stepped backside contact having a relief, wherein the relief provides a recess to increase a distance between the stepped backside contact and a first metal line on the backside;
a deep via connected to the top source/drain region; and
a backside power distribution network including the first metal line connected to the deep via and a second metal line connected to the stepped backside contact.

9. The semiconductor device of claim 8, wherein the relief is adjacent to the deep via.

10. The semiconductor device of claim 9, further comprising a dielectric layer between the first metal line and the second metal line on the backside.

11. The semiconductor device of claim 10, wherein the dielectric layer forms a T-shape in the relief and in a region between the first metal line and the second metal line.

12. The semiconductor device of claim 10, wherein the dielectric layer forms an S-shape in the relief and in a region between the first metal line and the second metal line.

13. The semiconductor device of claim 8, wherein the first metal line includes a supply voltage line in the backside power distribution network.

14. A method of fabricating a semiconductor device, comprising:
forming a bottom nanosheet stack and a top nanosheet stack on a substrate;
recessing the top nanosheet stack and a first portion the bottom nanosheet stack concurrently to expose of a first region of the substrate;
recessing a second portion of the bottom nanosheet stack to expose a second region of the substrate while concurrently etching a first recess in the substrate in the first region;
further recessing the first recess in the substrate in the first region and recessing a second recess in the substrate in the second region to form a stepped recess;
forming a sacrificial placeholder in the stepped recess;
forming a bottom source/drain region on the sacrificial placeholder and a top source/drain region over the bottom source/drain region;
forming a deep via connected to the top source/drain region;
removing the sacrificial placeholder; and
forming a stepped backside contact in place of the sacrificial placeholder, the stepped backside contact connected to the bottom source/drain region.

15. The method of claim 14, further comprising forming a backside power distribution network including a first metal line connected to the deep via and a second metal line connected to the stepped backside contact.

16. The method of claim 15, wherein the stepped backside contact includes a thicker portion and a thinner portion, and wherein the thinner portion provides increased distance between the stepped backside contact and the first metal line.

17. The method of claim 15, further comprising forming a dielectric layer between the first metal line and the second metal line.

18. The method of claim 17, wherein the dielectric layer forms a T-shape between the first metal line, the second metal line and the stepped backside contact.

19. The method of claim 17, wherein the dielectric layer forms an S-shape between the first metal line, the second metal line and the stepped backside contact.

20. The method of claim 15, wherein the stepped backside contact includes a relief that provides increased distance between the stepped backside contact and the first metal line.
